(19) United States
(12) Patent Application Publication
(10) Pub. No.: US 2009/0133921 A1
(43) Pub. Date: May 28, 2009

(54) FLEXIBLE PC BOARD MADE THROUGH A WATER CLEANING PROCESS

(75) Inventor: Victor Shi-Yueh Sheu, San-Chung City (TW)

Correspondence Address: PAI PATENT & TRADEMARK LAW FIRM, 1001 FOURTH AVENUE, SUITE 3200, SEATTLE, WA, 98154, US

(73) Assignee: ULT TECHNOLOGY CO., LTD., San-Chung City (TW)

(21) Appl. No.: 11/946,514

(22) Filed: Nov. 28, 2007

(51) Int. Cl. H05K 1/02; H05K 9/00

(52) U.S. Cl. 174/388; 174/254

(57) ABSTRACT

A flexible PC board made through a water cleaning process includes a substrate prepared from polymers or copolymers such as PET, PI, PP, PS, PMMA, PC, PU, PBT, ABS, nylon, etc. A release layer prepared from a hydrophilic material and printed on the substrate to leave a blank zone on the substrate according to a predetermined circuit pattern, and a conduction layer bonded to the blank zone to form a circuit pattern. An electroplating process may be employed to increase the thickness of the circuit pattern formed of the conduction layer. Through a water cleaning process, the release layer is removed from the substrate, and the desired flexible PC board is obtained for bonding to a member of an electronic product by means of injection or pressure casting molding.

### BACKGROUND OF THE INVENTION

(a) Field of the Invention

The present invention relates to a flexible printed circuit board and more particularly to a flexible printed circuit board made through a water cleaning process. The flexible printed circuit board so made is practical for bonding to a member of an electronic product through forming, trimming and injection molding or pressure casting molding. The invention has the advantages of simple manufacturing process, environmental friendliness, high quality, and high yield rate.

(b) Description of the Prior Art

Regular printed circuit boards include hard printed circuit boards and flexible printed circuit boards. The process for manufacturing a hard printed circuit board comprises forming internal wires through photoresist application, exposing, image developing, etching and photoresist removing steps so as to form a circuit pattern on a substrate, and then coarsening copper surface by employing black oxidation or brown oxidation for adhesion of insulation resin. Substrates for inner and outer layers are then laminated together. Interconnections between the inner and outer layers are made by means of making apertures by a mechanical drilling machine or laser apparatus and plating the apertures with a metal coating. After circuit formation, the outer layer of the circuit board is coated with a solder mask ink. Antioxidation surface treatment may be employed to enhance the strength of the surface against oxidation.

The process for manufacturing a flexible printed circuit board comprises forming a flexible insulative layer and a copper foil layer. Flexible printed circuit boards are commonly used in 3C products (computer, communication and consumer electronics), particularly, cell phones and LCD displays. Flexible printed circuit boards use many materials including resin, copper foil, adhesive, coverlay, FCCL (flexible copper clay laminate), etc.

The process for manufacturing a flexible printed circuit board (FPC) includes the steps of forming a circuit pattern by means of photodevelopment, etching, and acid/alkaline cleaning. Acid/alkaline cleaning causes a wastewater problem. Because wastewater from acid/alkaline cleaning has a high concentration, its treatment is complicated and very costly. Further, it brings pollution to the environment. In addition, circuit pattern quality control is another severe problem during acid/alkaline cleaning. Because of the aforesaid problems, conventional flexible printed circuit board manufacturing methods have a low yield rate.

### SUMMARY OF THE INVENTION

The present invention has been accomplished under the circumstances in view. The main object of the present invention is to provide a flexible printed circuit board which employs a water cleaning process to remove the removable layer instead of conventional etching and acid/alkaline cleaning, thereby simplifying the fabrication, meeting the environmental protection requirements, eliminating wastewater pollution problem, assuring high integrity of the circuit pattern, and increasing the yield rate.

Another object of the present invention is to provide a flexible printed circuit board by means of a water cleaning process, which, after shape forming and trimming, can be directly bonded to a member of a 4C product (computer, communication, consumer electronics and car electronics) during injection molding or pressure casting molding of the member, thereby simplifying the fabrication of the 4C product and enhancing the product competitiveness.

Still another object of the present invention is to provide a flexible printed circuit board by means of a water cleaning process, which has its bottom wall coated with a metal material such as Ni, Cr, Mg, or Al to form an EMI protective layer for protection against electromagnetic interference.

### BRIEF DESCRIPTION OF THE DRAWINGS

FIG. 1 is a schematic drawing shown a printed layer printed on a substrate during the fabrication of a flexible printed circuit board according to the present invention.

FIG. 2 corresponds to FIG. 1, showing a conduction layer formed in the blank zone and bonded to the substrate.

FIG. 3 corresponds to FIG. 2, showing a conduction layer formed on the substrate, and the printed layer removed from the substrate after the application of a water cleaning process.

FIG. 4 corresponds to FIG. 2, showing an electroplated layer formed on the conduction layer.

FIG. 5 corresponds to FIG. 4, showing the printed layer removed from the substrate after the application of a water cleaning process.

FIG. 6 corresponds to FIG. 5, showing an adhesion layer covered on the bottom side of the substrate for bonding the flexible printed circuit board to a member of an electronic product.

FIG. 7 corresponds to FIG. 5, showing an EMI layer covered on the bottom side of the substrate and an adhesion layer covered on the EMI layer for bonding the flexible printed circuit board to a member of an electronic product.

### DETAILED DESCRIPTION OF THE PREFERRED EMBODIMENTS

Referring to the annexed drawings in detail, a flexible printed circuit board made through a water cleaning process in accordance with the present invention comprises a substrate 1, a printed layer 2, and a conduction layer 3.

The substrate 1 is prepared from polymers or copolymers such as polyethylene terephthalate (PET), polyimide (PI), polypropylene (PP), polystyrene (PS), polymethylmethacrylate (PMMA), polycarbonate (PC), polyurethane (PU), polybutylene terephthalate (PBT), acrylonitrile butadiene styrene (ABS), nylon, etc.

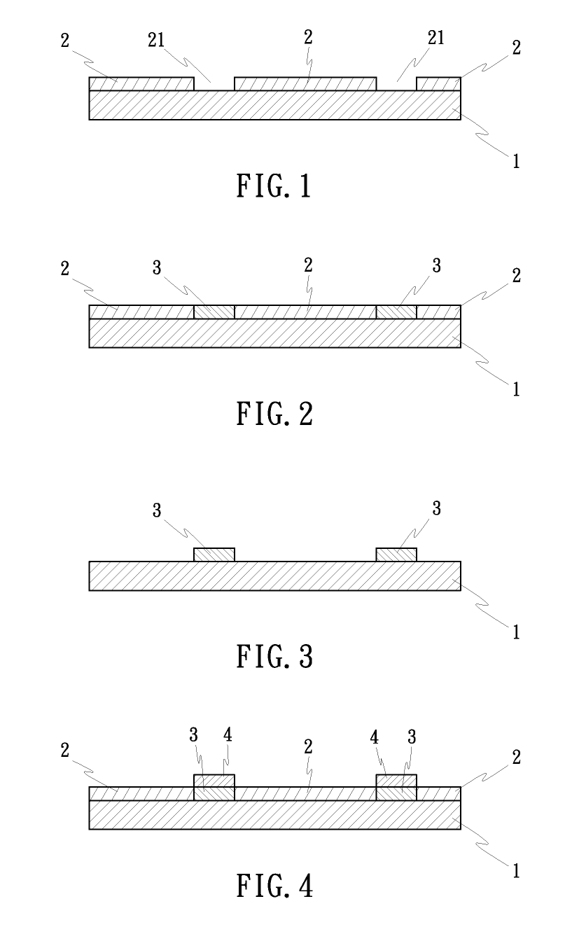

The printed layer 2, as shown in FIG. 1, is a removable layer prepared from a hydrophilic material that can be either transparent or opaque, and is printed on one side, namely, the top side of the substrate 1 according to a predetermined pattern such that a blank zone 21 not covered by the printed layer 2 is left on the top side of the substrate 1, corresponding to a predetermined circuit pattern. The printed layer 2 is a removable layer printed on the top side of the substrate 1 by means of any of a variety of printing techniques such as gravure printing, flexographic printing, lithographic printing, screen printing, or transfer printing. The hydrophilic material is an environmentally friendly material. The environmentally friendly material can be polyvinyl alcohol (PVA), polyvinyl pyrrolidone (PVP), pulp, talc, acrylic, silicone, melamine, or any other suitable material that is removable from the substrate 1 after being printed.

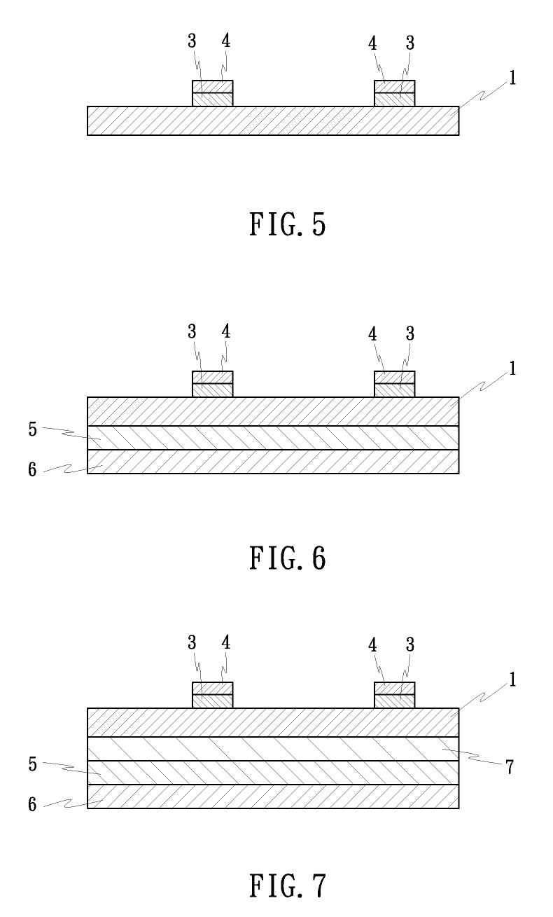

The conduction layer 3, as shown in FIG. 2, is formed by growing a conducting material in the blank zone 21 surrounded by the printed layer 2 on the substrate 1 by means of sputtering deposition, vapor deposition or printing process (see FIG. 2), and then the printed layer 2 is removed from the substrate 1 by means of a water cleaning process, and thus the desired circuit pattern constructed of the conduction layer 3 is formed on the top side of the substrate 1 (see FIG. 3). When necessary, an electroplated layer 4 can be plated on the conduction layer 3 with the same conducting material to increase the thickness of the circuit pattern before the water cleaning process (see FIG. 4). After the electroplated layer 4 is formed, the printed layer 2 is removed from the substrate 1 by means of water cleaning, and a high-thickness circuit pattern is formed on the top side of the substrate 1 (see FIG. 5). The need for thickness increasing is determined according to the conductivity (admittance) desired. This is not a requisite processing process.

The semi-finished flexible printed circuit board formed of the substrate 1, the printed layer 2 and the conduction layer 3, with the optional electroplated layer 4, then undergoes a water cleaning process to remove the printed layer (release layer) 2, leaving a circuit pattern of the conduction layer 3 (or the combination of the conduction layer 3 and the electroplated layer 4) on the top side of the substrate 1 (see FIGS. 3 and 5). This finished product thus obtained is not treated with any acid or alkaline cleaning process. Therefore, the fabrication of the flexible printed circuit board does not cause any wastewater pollution problem. Further, the circuit pattern formed of the conduction layer 3 is more complete, thus increasing the yield.

The flexible printed circuit board 2 can be made by means of multiple printing processes, i.e., the circuit pattern can be formed of multiple layers stacked on one another.

After forming and trimming, the flexible printed circuit board can be directly molded on an internal or external part of a 4C product (computer, communication, consumer electronics and car electronics) by means of injection molding or pressure casting molding techniques. This application is most suitable for the fabrication of an electronic tag for RFID (radio frequency identification) system. As a result, it will increase the competitiveness of the product in the market.

Referring to FIG. 6, an adhesion layer 5 may be covered on the other side, namely, the bottom side of the substrate 1 to facilitate bonding of the substrate 1 to a member 6 for a 4C product, thereby enabling the member 6 to have a predetermined circuit pattern.

Referring to FIG. 7, the bottom side of the substrate 1 may be coated with a metal material such as Ni, Cr, Mg, Al, etc. to form an EMI protective layer 7 for protection against electromagnetic interference, and then an adhesion layer 5 is covered on the outer surface of the EMI protective layer 7 for bonding to a member of a 4C product.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A flexible printed circuit board made through a water cleaning process, said flexible printed circuit board comprising a substrate, a printed layer, and a conduction layer, wherein said substrate is made out of a polymer or copolymer compound;
said printed layer is a removable layer prepared from a hydrophilic environmentally friendly material and printed on a first side of said substrate according to a predetermined pattern such that a blank zone not covered by said printed layer is left on the first side of said substrate, corresponding to a predetermined circuit pattern;
said conduction layer is prepared from an electrically conductive material and bonded to said blank zone, forming a circuit pattern;
wherein said printed layer is removed from said substrate by means of a water cleaning process after said conduction layer is formed on said substrate.

2. The flexible printed circuit board as claimed in claim 1, wherein said substrate is made out of polyethylene terephthalate (PET), polyimide (PI), polypropylene (PP), polystyrene (PS), polymethylmethacrylate (PMMA), polycarbonate (PC), polyurethane (PU), polybutylene terephthalate (PBT), acrylonitrile butadiene styrene (ABS), nylon or a mixture thereof.

3. The flexible printed circuit board as claimed in claim 1, wherein said hydrophilic environmentally friendly material is polyvinyl alcohol (PVA), polyvinyl pyrrolidone (PVP), pulp, talc, acrylic, silicon, melamine, or a mixture thereof.

4. The flexible printed circuit board as claimed in claim 1, wherein said conduction layer is bonded to said blank zone by means of sputtering deposition, a vapor deposition process or a printing process.

5. The flexible printed circuit board as claimed in claim 1, wherein the circuit pattern formed of said conduction layer is treated with an electroplating process to increase the thickness of said conduction layer.

6. The flexible printed circuit board as claimed in claim 1, wherein said printed layer comprises multiple layers which are made through multiple printing processes and stacked on one another.

7. The flexible printed circuit board as claimed in claim 1, further comprising an adhesion layer covered on a second side of said substrate opposite to said first side for bonding to a member of an electronic product by means of injection or pressure casting molding.

8. The flexible printed circuit board as claimed in claim 1, further comprising an EMI protective layer prepared from an electromagnetic interference friendly metal material and covered on a second side of said substrate opposite to said first side, and an adhesion layer covered on one side of said EMI protective layer opposite to said substrate for bonding to a member of an electronic product by means of injection or pressure casting molding.
